(19) United States
(12) Patent Application Publication
(10) Pub. No.: US 2026/0040894 A1
(43) Pub. Date: Feb. 5, 2026

(54) Method of Increasing a Volume and a Height of a Solder Bump

(71) Applicant: Pac Tech - Packaging Technologies GmbH, Nauen (DE)

(72) Inventor: Matthias Fettke, Berlin (DE)

(21) Appl. No.: 18/990,187

(22) Filed: Dec. 20, 2024

(30) Foreign Application Priority Data
Jul. 31, 2024 (DE) 10 2024 121 794.4

(51) Int. Cl. H01L 23/00; H01L 21/66

(52) U.S. Cl. CPC H01L 24/11; H01L 22/12; H01L 2224/11318; H01L 2224/11849; H01L 2224/11901; H01L 2924/014

(57) ABSTRACT

A method of increasing a volume and a height of a solder bump present on a contact pad of a substrate is provided, including the steps: a) placing a solder ball having a predetermined volume in a capillary which is placed over the solder bump, b) liquefying the solder ball by applying laser energy from the laser source to the solder ball through the capillary, c) ejecting the liquefied solder ball from the capillary onto the solder bump by applying pressurized gas to the liquefied solder ball through the capillary, and d) melting the solder bump by transferring thermal and kinetic energy to the solder bump from the ejected liquefied solder ball and merging the liquefied solder ball with the melted solder bump.

### BACKGROUND OF THE INVENTION

### Field of the invention

The present disclosure relates to a method of increasing a volume and a height of a solder bump present on a contact pad of a substrate.

### Description of Related Art

Document U.S. Pat. No. 6,468,893 B2 discloses a method of forming solder bumps by a), forming first solder paste layers on respective electrodes/pads of a substrate by printing a solder paste on the electrodes/pads using a first mask, b) forming first solder bumps on the respective electrodes/pads by melting the first solder paste layers and solidifying the first solder paste layers, after removing the first mask, c) forming second solder paste layers on the respective first solder bumps by printing a solder paste on the first solder bumps using a second mask, and d) forming second solder bumps on the respective electrodes/pads by melting the first solder bumps and the second solder paste layers to be integrated together and by solidifying the first solder bumps and the second solder paste layers, after removing the second mask. With the above method, solder bumps having a desired volume or height can be formed or printed on a substrate.

Generally, it is known from the prior art to level heights of multiple solder bumps present on a substrate using masks comprising openings and applying solder paste onto the solder bumps through the openings in case the solder bumps have different heights. Solder bumps having different heights may lead to problems in specific bonding applications, for example when connecting specific electronic components, e.g. a chip, or another substrate, to the substrate via the solder bumps. In particular, high compression forces need to be applied when attaching the electronic components or the another substrate in order to avoid contact defects like openings after the attaching. Therefore, the openings of the mask may individually be sized such that all solder bumps have a uniform size after solder paste is applied to the solder bumps having different heights via the mask. The solder bumps may be heated in a reflowing furnace in order to achieve a reliable bond.

### SUMMARYOF THE INVENTION

In view of the above described problem it is an object to provide a method of increasing a volume and a height of a solder bump present on a contact pad of a substrate with which the volume and height of a solder bump can be adjusted easily and without a mask. Further, it is an object to provide a solder ball jetting apparatus for carrying out such a method.

This object is solved by the method according to independent claim 1 and independent claim 10. Preferred embodiments are subject of the dependent claims.

The present disclosure discloses a method of increasing a volume and a height of a solder bump present on a contact pad of a substrate, which may comprise the steps: a) placing a solder ball having a predetermined volume in a capillary which is placed over the solder bump, b) liquefying the solder ball by applying laser energy from the laser source to the solder ball through the capillary, c) ejecting the liquefied solder ball from the capillary onto the solder bump by applying pressurized gas to the liquefied solder ball through the capillary, and d) melting the solder bump by transferring thermal and kinetic energy to the solder bump from the ejected liquefied solder ball and merging the liquefied solder ball with the melted solder bump.

With the method described above, energy, in particular in the form of kinetic energy and thermal energy, of the liquefied solder ball can be used to melt the solder bump on contact with the liquefied solder ball, so that the liquefied solder ball can enter the solder bump completely and merge with the solder bump. The method allows a solder bump to be easily increased in volume and height without the use of a mask. It is noted that the term “solder ball” does not limit the shape of the solder ball to a perfect spherical shape, but includes any solder preform that are substantially spherical. The material of the solder ball may differ from the material of the solder bump. For example, the solder ball may be solder alloy SAC305 and the solder bump may be made of a SnBi alloy.

In a further embodiment, during step d) laser energy, preferably from the laser source, is additionally applied to the solder bump.

Specifically, the laser source can be activated during steps a) to d) in order to ensure that the solder ball is liquefied in step b) as well as that the liquefied solder ball completely enters and merges with the solder bump in step d).

In a further embodiment, before step a) laser energy, preferably from the laser source, is applied to the solder bump.

By transferring laser energy, preferably from the laser source, to the solder bump before step a), the solder bump can be preheated or pre-melted such that the solder ball can easily enter the solder bump completely and merge with the solder bump in step d).

In a further embodiment, the thermal & kinetic energy of the liquefied solder ball and/or the laser energy required for melting the solder bump can be adjusted by setting the pressure of the gas to 25 mbar-130 mbar and/or the laser energy to 2 mJ-150 mJ.

In a further embodiment, the substrate comprises at least two solder bumps of different heights, and wherein steps a) to d) are carried out on a first solder bump having a lesser height than a second solder bump having a greater height so as to adjust the height of the first solder bump to the height of the second solder bump.

With the above method, the height of the first solder bump can be easily adjusted to the height of the second solder bump. In particular, the method can be used to adjust the heights of all solder bumps present on the substrate to the height of the highest solder bump so that a coplanar connection plane is created on the substrate. Then, electronic components, e.g. chips, or other substrates can be securely connected to the substrate without contact defects, for example solder bridges.

In a further embodiment, the method further comprises the steps: e) measuring a difference in height between the first solder bump and the second solder bump, and f) calculating a total volume of solder material required to be applied to the first solder bump so as to increase the volume and height of the first solder bump to reach the height of the second solder bump, wherein steps e) and f) are carried out before steps a) to d) and wherein steps a) to d) are repeated if the predetermined volume of the solder ball is smaller than the calculated total volume of solder material.

Thus, by carrying out the above method, the height of the first solder bump can be increased to the height of the second solder bump easily and reliably. The measuring of the difference in height between the first solder bump and the second solder bump may be carried out in any way. However, an optical measurement, e.g. using a camera or a laser, is preferred. By calculating the total volume of solder material required to be applied to the first solder bump so as to increase the volume and height of the first solder bump to reach the height of the second solder bump, a processing speed can be increased as a comparison of heights of the second solder bump and the first solder bump does not have to be carried out after applying each liquefied solder ball to the first solder bump.

In a further embodiment, the method further comprises the steps: g) measuring an actual height of the solder bump, and h) calculating a total volume of solder material to be applied to the solder bump so as to increase a volume and height of the solder bump to reach a predetermined target height, wherein steps g) and h) are carried out before steps a) to d) and wherein steps a) to d) are repeated if the predetermined volume of the solder ball is smaller than the calculated total volume of solder material.

By carrying out the above method, the height of the solder bump can be increased to the target height easily and reliably. By calculating the total volume of solder material required to be applied to the solder bump so as to increase the volume and height of the solder bump to reach the predetermined target height, a processing speed can be increased as a measurement of the height of the solder bump does not have to be carried out after applying each liquefied solder ball to the solder bump.

In a further embodiment, the measuring of the actual height of the solder bump is carried out optically.

An optical measurement of the height of the solder bump, e.g. using a camera or a laser, is preferred.

In a further embodiment, the predetermined volume of the solder ball is from 1,4e⁻⁵ mm³ to 0,015 mm³, preferably 3,30.5 mm³.

That is, by applying solder balls having a relatively small predetermined volume from 1,4e⁻⁵ mm³ to 0,015 mm³ the volume and height of the solder bump can be adjusted extremely precisely. It is possible to compensate for even the smallest height differences of solder bumps in the micrometer range and form a coplanar connection plane on the substrate.

The present disclosure discloses a solder ball jetting apparatus comprising a capillary, a laser source, a pressurized gas source, and a controller, which may be configured to control the capillary, the laser source and the pressurized gas source so as to carry out a method according to any of the above aspects. Specifically, the solder ball jetting apparatus may be configured so as to carry out a method comprising the steps of: a) placing a solder ball having a predetermined volume in the capillary which is placed over a solder bump present on a contact pad of a substrate, b) liquefying the solder ball by applying laser energy from the laser source to the solder ball through the capillary, c) ejecting the liquefied solder ball from the capillary onto the solder bump by applying pressurized gas from the pressurized gas source to the liquefied solder ball through the capillary, and d) melting the solder bump by transferring thermal and kinetic energy to the solder bump from the ejected liquefied solder ball and merging the liquefied solder ball with the melted solder bump.

The solder balls may be stored in a reservoir and separated by a rotating singulation disc, which also transfers the solder balls to the capillary. The solder ball may drop into the capillary, and block a capillary opening by having a diameter slightly greater than a diameter of the capillary opening. The laser source may apply a short near infrared laser pulse interacting in a millisecond range to liquefy the solder ball. The pressurized gas source may apply pressurized gas, e.g. N₂, into the capillary such that the liquefied solder ball can be ejected from the capillary onto the solder bump. The energy of the liquefied solder ball is directly related to the speed at which the liquefied solder ball is ejected from the capillary. The speed of the liquefied solder ball in turn depends on the pressure of the pressurized gas source controlled by the controller. The above solder ball jetting apparatus or the capillary may be controlled by the controller so as to be movable along three axes to be placed over any solder bump on the substrate whose volume and height is to be increased. The controller may further be configured to calculate a total volume of solder material required to be applied the solder bump so as to increase the volume and height of the solder bump to reach a height of a further solder bump or to reach a predetermined height.

With the apparatus described above, energy, in particular in the form of kinetic energy and thermal energy, of the liquefied solder ball can be used to melt the solder bump on contact with the liquefied solder ball, so that the liquefied solder ball can enter the solder bump completely and merge with the solder bump. The apparatus allows a solder bump to be easily increased in volume and height without the use of a mask.

Further, during step d) laser energy, preferably from the laser source, can additionally be applied to the solder bump. That is, the laser source can be activated during steps a) to d) in order to ensure that the solder ball is liquefied in step b) as well as that the liquefied solder ball completely enters and merges with the solder bump in step d).

The present disclosure discloses a controller for a solder ball jetting apparatus comprising a capillary, a laser source, and a pressurized gas source, wherein the controller may be configured to control the capillary, the laser source and the pressurized gas source so as to carry out a method according to any of the above aspects. Specifically, the controller for a solder ball jetting apparatus may be configured so as to carry out a method comprising the steps of: a) placing a solder ball having a predetermined volume in the capillary which is placed over a solder bump present on a contact pad of a substrate, b) liquefying the solder ball by applying laser energy from the laser source to the solder ball through the capillary, c) ejecting the liquefied solder ball from the capillary onto the solder bump by applying pressurized gas to the liquefied solder ball through the capillary, and d) melting the solder bump by transferring thermal and kinetic energy to the solder bump from the ejected liquefied solder ball and merging the liquefied solder ball with the melted solder bump. The solder ball jetting apparatus or the capillary may be controlled by the controller so as to be movable along three axes to be placed over any solder bump on the substrate whose volume and height is to be increased. The controller may further be configured to calculate a total volume of solder material required to be applied the solder bump so as to increase the volume and height of the solder bump to reach a height of a further solder bump or to reach a predetermined height.

The pressurized gas source may apply pressurized gas, e.g. N₂, into the capillary such that the liquefied solder ball can be ejected from the capillary onto the solder bump. The energy of the liquefied solder ball is directly related to the speed at which the liquefied solder ball is ejected from the capillary. The speed of the liquefied solder ball in turn depends on the pressure of the pressurized gas source controlled by the controller.

With the controller described above, energy, in particular in the form of kinetic energy and thermal energy, of the liquefied solder ball can be controlled and used to melt the solder bump on contact with the liquefied solder ball, so that the liquefied solder ball can enter the solder bump completely and merge with the solder bump. The controller allows a solder bump to be easily increased in volume and height without the use of a mask.

Further, during step d) laser energy, preferably from the laser source, can additionally be applied to the solder bump. That is, the laser source can be activated during steps a) to d) in order to ensure that the solder ball is liquefied in step b) as well as that the liquefied solder ball completely enters and merges with the solder bump in step d). In the following, an embodiment of the present disclosure is described with reference to several figures:

### BRIEF DESCRIPTION OF THE DRAWINGS

FIG. 1 shows a front view of a solder ball jetting apparatus according to an embodiment, which applies solder balls to a solder bump present on a substrate;

FIG. 2 shows an enlarged front view of the solder ball jetting apparatus and the solder bump of FIG. 1; and

FIG. 3 shows an application of the solder ball jetting apparatus for levelling heights of solder bumps present on an uneven substrate.

The figures are merely schematic in nature and are intended solely for the purpose of understanding the disclosure. The proportions of the elements shown in the figures have been adjusted accordingly to make the disclosure easier to understand.

### DETAILED DESCRIPTION OF THE PREFERRED EMBODIMENTS

FIG. 1 discloses a solder ball jetting apparatus 10 according to an embodiment comprising a movable capillary 1, a laser source (not shown), a pressurized gas source (not shown) and a controller (not shown) configured to control the capillary 1, the laser source and the pressurized gas source.

As can be seen in FIG. 1, capillary 1 is placed over a solder bump Sa at a certain distance, wherein the solder bump 5a is present on a contact pad 3 of a substrate 4. Further solder bumps 5b are present on contact pads 3 on the substrate 4, wherein the solder bump 5a has a lesser height than the solder bumps 5b, which each have the same height. Although not shown in FIG. 1, a difference in height between the solder bump 5a and the solder bump 5b has been optically measured, and a total volume of solder material required to be applied to the solder bump 5a so as to increase the volume and the height of the solder bump 5a to reach the height of the solder bumps 5b has been calculated. Further, it has been calculated how many solder balls having a predetermined volume correspond to the total volume of solder material.

Then, a solder ball 2 having the predetermined volume, which has been placed in the capillary 1 and liquefied by the laser source, which has applied laser energy through the capillary 1, is being ejected from the capillary 1 onto the solder bump 5a. Specifically, pressurized gas from the pressurized gas source is applied to the liquefied solder ball 2 through the capillary 1, so that the liquefied solder ball 2 having a specific temperature is ejected from the capillary 1 at a specific speed. In other words, the liquefied solder ball 2 being ejected from the capillary 1 has a certain kinetic energy and a certain thermal energy depending on the temperature and speed of the solder ball 2. The speed of the liquefied solder ball 2 in turn depends on the pressure of the pressurized gas, which is controlled by the controller.

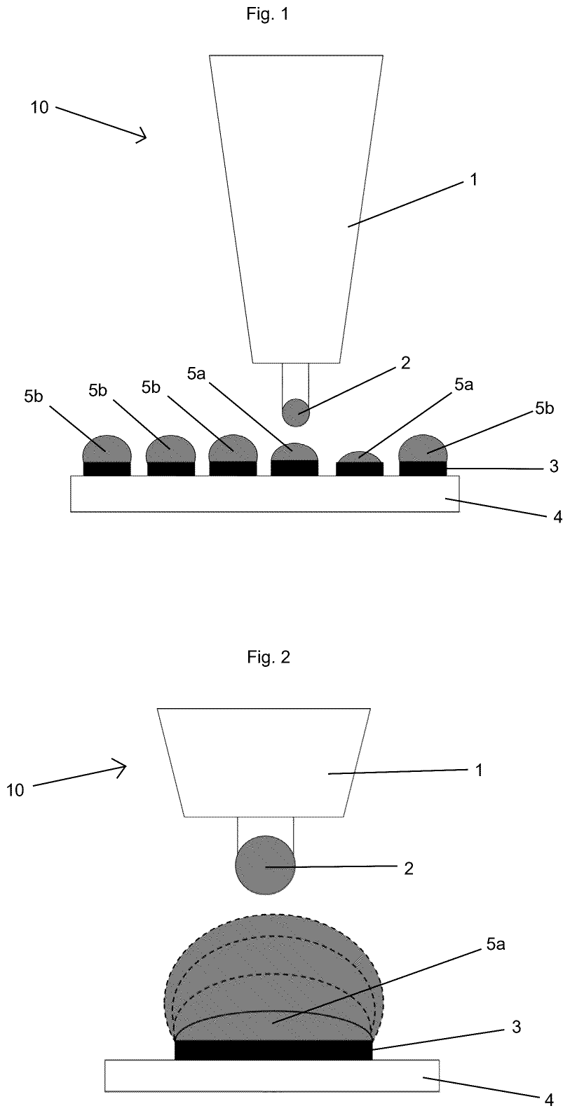

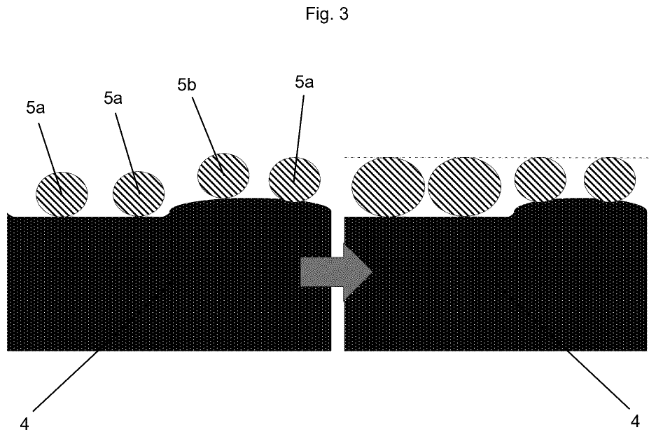

The kinetic energy and thermal energy of the liquefied solder ball 2 is used to melt the solder bump 5a on contact with the liquefied solder ball 2, so that the liquefied solder ball 2 can enter the solder bump 5a completely and merge with the solder bump 5a. Additionally, laser energy from the laser source can be transferred to the solder bump 5a in order to ensure that the liquefied solder ball 2 completely enters and merges with the solder bump 5a. Then, the method described above is repeated until the calculated number of solder balls 2 has been applied to the solder bump 5a, i.e. until the total volume of solder material has been applied to the solder bump 5a. As indicated by the dash lines in FIG. 2, a volume and a height of the solder bump 5a is increased with each solder ball 2 that is applied into the solder bump 5a. It is again noted that the solder ball 2 completely enters the solder bump 5a on contact with the solder bump 5a and merges with the solder bump 5a so that the solder bump 5a is given a uniform structure. With the solder ball jetting apparatus 10 and the method described above, the solder bump 5a can be easily increased in volume and height without the use of a mask.

Further, as shown on the left-hand side of FIG. 3, an uneven substrate 4 is provided on which a plurality of solder bumps are arranged. It is noted that no contact pads are depicted in FIG. 3. The solder bumps have the same size. However, due to the unevenness of the substrate 4, the solder bump indicated with reference sign 5b is the highest with respect to a lower surface of the substrate 4. The solder bumps 5a can be enlarged using the solder ball jetting apparatus 10 and the method described above such that a coplanar connection plane is created, which is indicated by a dotted line on the right-hand side in FIG. 3.

In particular, the solder ball jetting apparatus 10 and method can be used to adjust the heights of all solder bumps present on the substrate 4 having a lesser height than a height of the highest solder bump so that a coplanar connection plane is created on the substrate 4, irrespective of whether the different heights of the solder bumps result from the solder bumps having different sizes, as shown in FIG. 1, or from the substrate 4 being uneven, as shown in FIG. 3. Then, electronic components, e.g. chips, or other substrates can be securely connected to the substrate 4 without contact defects, for example solder bridges. Generally, by the above described method, each individual solder bump present on a substrate can be easily adjusted in height as desired.

1. A method of increasing a volume and a height of a solder bump present on a contact pad of a substrate, comprising the steps:
a) placing a solder ball having a predetermined volume in a capillary which is placed over the solder bump,
b) liquefying the solder ball by applying laser energy from the laser source to the solder ball through the capillary,
c) ejecting the liquefied solder ball from the capillary onto the solder bump by applying pressurized gas to the liquefied solder ball through the capillary, and
d) melting the solder bump by transferring thermal and kinetic energy to the solder bump from the ejected liquefied solder ball and merging the liquefied solder ball with the melted solder bump.

2. The method according to claim 1, wherein during step d) laser energy, preferably from the laser source, is additionally applied to the solder bump.

3. The method according to claim 1, wherein before step a) laser energy, preferably from the laser source, is applied to the solder bump.

4. The method according to claim 1, wherein the thermal and kinetic energy of the liquefied solder ball and/or the laser energy required for melting the solder bump can be adjusted by setting the pressure of the gas to 25 mbar-130 mbar and/or the laser energy to 2 mJ-150 mJ.

5. The method according to claim 1, wherein the substrate comprises at least two solder bumps of different heights, and wherein steps a) to d) are carried out on a first solder bump having a lesser height than a second solder bump having a greater height so as to adjust the height of the first solder bump to the height of the second solder bump.

6. The method according to claim 5, further comprising the steps:
e) measuring a difference in height between the first solder bump and the second solder bump, and
f) calculating a total volume of solder material required to be applied to the first solder bump so as to increase the volume and height of the first solder bump to reach the height of the second solder bump,
wherein steps e) and f) are carried out before steps a) to d) and
wherein steps a) to d) are repeated if the predetermined volume of the solder ball is smaller than the calculated total volume of solder material.

7. The method according to claim 1, further comprising the steps:
g) measuring an actual height of the solder bump, and
h) calculating a total volume of solder material to be applied to the solder bump so as to increase a volume and height of the solder bump to reach a predetermined target height,
wherein steps g) and h) are carried out before steps a) to d) and
wherein steps a) to d) are repeated if the predetermined volume of the solder ball is smaller than the calculated total volume of solder material.

8. The method according to claim 6, wherein the measuring of the actual height of the solder bump is carried out optically.

9. The method according to claim 1, wherein the predetermined volume of the solder ball is from 1,4e⁻⁵ mm³ to 0,015 mm³, preferably 3,3e⁻⁵ mm³.

10. A solder ball jetting apparatus comprising a capillary, a laser source, a pressurized gas source, and a controller configured to control the capillary, the laser source and the pressurized gas source so as to carry out a method comprising the steps:
a) placing a solder ball having a predetermined volume in the capillary which is placed over a solder bump present on a contact pad of a substrate,
b) liquefying the solder ball by applying laser energy from the laser source to the solder ball through the capillary,
c) ejecting the liquefied solder ball from the capillary onto the solder bump by applying pressurized gas from the pressurized gas source to the liquefied solder ball through the capillary, and
d) melting the solder bump by transferring thermal and kinetic energy to the solder bump from the ejected liquefied solder ball and merging the liquefied solder ball with the melted solder bump.

11. A controller for a solder ball jetting apparatus comprising a capillary, a laser source, and a pressurized gas source, wherein the controller is configured to control the capillary, the laser source and the pressurized gas source so as to carry out a method comprising the steps:
a) placing a solder ball having a predetermined volume in the capillary which is placed over a solder bump present on a contact pad of a substrate,
b) liquefying the solder ball by applying laser energy from the laser source to the solder ball through the capillary,
c) ejecting the liquefied solder ball from the capillary onto the solder bump by applying pressurized gas to the liquefied solder ball (2) through the capillary, and
d) melting the solder bump by transferring thermal and kinetic energy to the solder bump from the ejected liquefied solder ball and merging the liquefied solder ball with the melted solder bump.
